(19) United States
(12) Patent Application Publication
(10) Pub. No.: US 2026/0029477 A1
(43) Pub. Date: Jan. 29, 2026

(54) ESTIMATION DEVICE, DIAGNOSTIC DEVICE, ESTIMATION METHOD, ESTIMATION PROGRAM, AND DIAGNOSTIC METHOD

(71) Applicant: GS Yuasa International Ltd., Kyoto-shi, Kyoto (JP)

(72) Inventors: Shuhei SATO, Kyoto-shi, Kyoto (JP); Nan UKUMORI, Kyoto-shi, Kyoto (JP); Ryosuke TAKEHANA, Kyoto-shi, Kyoto (JP)

(21) Appl. No.: 18/993,176

(22) PCT Filed: Jun. 21, 2023
(86) PCT No.: PCT/JP2023/022952

§ 371 Date: Jan. 10, 2025

(30) Foreign Application Priority Data
Jul. 12, 2022 (JP) 2022-111733

(51) Int. Cl. G01R 31/3842; H01M 10/42

(52) U.S. Cl. CPC G01R 31/3842; H01M 10/4285

(57) ABSTRACT

An estimation device includes: an acquisition portion acquiring time-series data of a current and a voltage of an energy storage device; a calculation portion calculating time-series data of an amount of electricity or an SOC, based on the time-series data of the current and the voltage acquired by the acquisition portion; a generation portion generating a partial charge/discharge profile of the energy storage device, based on the time-series data of the current and the voltage acquired by the acquisition portion and the time-series data of the amount of electricity or the SOC calculated by the calculation portion; and an estimation portion estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

### CROSS REFERENCE TO RELATED APPLICATIONS

This application is a National Stage Application, filed under 35 U.S.C. § 371, of International Application No. PCT/JP2023/022952, filed Jun. 21, 2023, which international application claims priority to and the benefit of Japanese Application No. 2022-111733, filed Jul. 12, 2022; the contents of both of which are hereby incorporated by reference in their entirety.

### BACKGROUND

### Technical Field

The present application generally relates to an estimation device, a diagnostic device, an estimation method, an estimation program, and a diagnostic method.

### Description of Related Art

An energy storage device has been widely used in an uninterruptible power supply device, a DC or an AC power supply device, which is included in a stabilized power supply, and the like. In addition, use of the energy storage device in a large-scale power system, which stores renewable energy or power generated by an existing power generation system is expanding.

It is known that deterioration of an energy storage device progresses as a result of repetition of charging and discharging, and its full charge capacity gradually decreases. JP 2015-121520 A and related literatures disclose a technology of a complete charge and discharge method in which some energy storage devices are removed from an energy storage system mounted with energy storage devices, the removed energy storage devices are charged to a fully charged state, and then the energy storage devices are completely discharged with a constant discharge current, thereby measuring a capacity of the energy storage devices.

### BRIEF SUMMARY

When the complete charge and discharge method is employed, it is necessary to stop an operation of the energy storage system. It is also conceivable to use, from operation data (an operation pattern) of the energy storage system, a limited portion (a part of the operation pattern) in which a capacity diagnosis of an energy storage device can be performed, without stopping an operation of the energy storage system. However, since only partial discharge characteristic can be acquired in this method, it is difficult to enhance accuracy of capacity diagnosis.

A main object of the present disclosure is to provide an estimation device and the like that can accurately estimate an overall discharge characteristic of an energy storage device.

An estimation device according to an aspect of the present disclosure includes: an acquisition portion that acquires time-series data of a current and a voltage of an energy storage device; a calculation portion that calculates time-series data of an amount of electricity or an SOC, based on the time-series data of the current and the voltage acquired by the acquisition portion; a generation portion that generates a partial charge/discharge profile of the energy storage device, based on the time-series data of the current and the voltage acquired by the acquisition portion and the time-series data of the amount of electricity or the SOC calculated by the calculation portion; and an estimation portion that estimates an overall discharge characteristic of the energy storage device, based on a parameter representing an internal state amount of the energy storage device adjusted in such a way that a profile of a predetermined section in the overall discharge characteristic of the energy storage device approaches the partial charge/discharge profile.

According to the present disclosure, the overall discharge characteristic of the energy storage device can be estimated with accuracy.

### BRIEF DESCRIPTION OF THE FIGURES

FIG. 1 is a diagram illustrating a configuration example of an estimation device and a diagnostic device.

FIG. 2 is a diagram illustrating a configuration of a power generation system.

FIG. 3 is a diagram illustrating a configuration example of a bank.

FIG. 4 is a functional block diagram illustrating a configuration example of the estimation device.

FIG. 5 is a diagram illustrating an example of current data.

FIG. 6 is a diagram illustrating an example of voltage data.

FIG. 7 is a diagram illustrating an example of a partial charge/discharge profile.

FIG. 8 is a diagram illustrating another example of the partial charge/discharge profile.

FIG. 9 is a diagram illustrating an internal state amount parameter.

FIG. 10 is a diagram illustrating an example of a correspondence relationship between a discharge capacity of an energy storage device and an internal state amount parameter.

FIG. 11 is a diagram explaining a method of estimating an overall discharge characteristic.

FIG. 12 is a flowchart illustrating an example of a processing procedure to be executed by an estimation device and a diagnostic device.

FIG. 13 is a flowchart illustrating an example of a processing procedure to be executed by an estimation device according to a second embodiment.

### DETAILED DESCRIPTION OF VARIOUS EMBODIMENTS

(1) An estimation device according to an aspect of the present disclosure includes: an acquisition portion that acquires time-series data of a current and a voltage of an energy storage device; a calculation portion that calculates time-series data of an amount of electricity or a state of charge (SOC), based on the time-series data of the current acquired by the acquisition portion; a generation portion that generates a partial charge/discharge profile of the energy storage device, based on the time-series data of the voltage acquired by the acquisition portion and the time-series data of the amount of electricity or the SOC calculated by the calculation portion; and an estimation portion that estimates an overall discharge characteristic of the energy storage device, based on a parameter representing an internal state amount of the energy storage device adjusted in such a way that a profile of a predetermined section in the overall discharge characteristic of the energy storage device approaches the partial charge/discharge profile.

The “partial charge/discharge profile” means a partial charge and discharge process in the energy storage device, and the term “partial” is used to distinguish it from the overall discharge characteristic. The partial charge/discharge profile is a part of a charge and discharge profile between an upper limit voltage and a lower limit voltage set for the energy storage device, or a part of a charge and discharge profile between an upper limit SOC and a lower limit SOC set for the energy storage device. The “overall discharge characteristic” is a characteristic indicated by a continuous discharge curve from an upper limit voltage to a lower limit voltage set for the energy storage device, or a characteristic indicated by a continuous discharge curve from an upper limit SOC to a lower limit SOC set for the energy storage device. The “predetermined section” may be, for example, a section of a capacity corresponding to the partial charge/discharge profile within the total capacity in overall discharge characteristics. The term “approach” may mean, for example, that a difference between a profile of a predetermined section in the overall discharge characteristic and the partial charge/discharge profile approaches zero.

According to the above configuration, the overall discharge characteristic of the energy storage device can be estimated based on time-series data of current and voltage acquired in an actual operation pattern, without stopping the operation of the energy storage system or without operating the energy storage system in a specific operation pattern for capacity diagnosis. Further, according to the above configuration, by using a parameter representing an appropriately adjusted internal state amount of the energy storage device, it is possible to accurately estimate the overall discharge characteristic even in a region other than a voltage region or an SOC region acquired in an actual operation pattern. The overall discharge characteristic can be estimated with accuracy, regardless of the type of a load to be applied to the energy storage device.

As described above, the estimation device estimates, based on a partial charge/discharge profile related to a part of a voltage region (SOC region) acquired in an actual operation pattern, overall discharge characteristics including other (all) voltage regions. Depending on the voltage region in the charge/discharge profile, the estimation accuracy of the overall discharge characteristics may be lowered. Namely, the estimation accuracy of the overall discharge characteristics may be reduced depending on the type of load applied to the energy storage device.

For example, when the acquired time-series data is unevenly distributed in a specific voltage region (e.g., a slope portion of the voltage), the region of the charge/discharge profile is relatively narrow. Further, even in a case where time-series data over a relatively wide voltage range is acquired, when the charge/discharge current is unbalanced, a region in which a partial charge/discharge profile can be generated becomes narrow. When the overall discharge characteristic is estimated based on the partial charge/discharge profile related to such a local region, for example, in a voltage region away from the voltage region of the partial charge/discharge profile, a shape of the estimated overall discharge characteristic may deviate from a shape of the actual (true value) overall discharge characteristic.

According to the above-described configuration, a parameter representing an internal state amount (hereinafter, also referred to as an internal state amount parameter) is adjusted in such a way that the overall discharge characteristic approaches the partial charge/discharge profile. The internal state amount is an element to specify an overall shape of the discharge characteristic. Even in a case where only a local partial charge/discharge profile is acquired, the shape of the overall discharge characteristic can be suitably expressed in all voltage regions set for the energy storage device, by using the internal state amount parameter adjusted based on local information. The overall discharge characteristic can be estimated with accuracy, regardless of the type of a load to be applied to the energy storage device.

(2) The estimation device according to the above (1) may include an adjustment portion that adjusts the parameter, based on a correspondence relationship between a capacity of the energy storage device and the parameter.

The “capacity of an energy storage device” means a total amount of electricity which is expressed when the energy storage device is discharged from a fully charged state (SOC 100%) to SOC 0% at a constant current value. Hereinafter, the capacity of the energy storage device is also referred to as a discharge capacity. The discharge capacity has a unique value in accordance with the overall discharge characteristics of the energy storage device. Namely, the overall discharge characteristic approaching the partial charge/discharge profile corresponds to the overall discharge characteristic indicating a predetermined discharge capacity approaching the partial charge/discharge profile.

When the internal state amount parameter is adjusted to fit the overall discharge characteristic to the partial charge/discharge profile, values of the internal state amount parameter that can be candidates for adjustment are enormous. In particular, when there are a plurality of types of internal state amount parameters, since there are a plurality of combinations of internal state amount parameters that can be candidates for adjustment, it is difficult to uniquely determine a solution, and the estimation accuracy decreases. Further, as the region of the partial charge/discharge profile is narrower, the charge/discharge profile is determined from a less amount of information, and therefore, as described above, the number of combinations of internal state amount parameters that can be candidates for adjustment also increases, and the adjustment work of the internal state amount parameters becomes more difficult.

According to the estimation device described in the above (2), it is possible to efficiently specify the internal state amount parameter by using the correspondence relationship between the discharge capacity and the internal state amount parameter. By obtaining the value of the internal state amount parameter corresponding to the capacity of the energy storage device in advance and storing the correspondence relationship therebetween, the calculation load during estimation can be reduced. For example, by storing the correspondence relationship for each of the plurality of internal state amount parameters, a combination of respective internal state amount parameter values corresponding to one capacity value can be specified, and therefore, adjustment processing of the internal state amount parameters becomes easy, and the estimation accuracy can be improved.

(3) In the estimation device according to the above (2), the adjustment portion may adjust the parameter in such a way that a profile of a predetermined section in the overall discharge characteristic related to a capacity associated with the parameter approaches the partial charge/discharge profile.

According to the estimation device according to the above (3), by adjusting the capacity value indicated by the overall discharge characteristics, it is possible to easily adjust the internal state amount parameter, based on the capacity value and the correspondence relationship.

(4) In the estimation device according to the above (2) or (3), a plurality of the correspondence relationships may be set in accordance with a state of the energy storage device, and the adjustment portion may select a correspondence relationship to be used to specify the parameter in accordance with the state of the energy storage device.

According to the estimation device according to the above (4), the overall discharge characteristics can be generated in consideration of the state of the energy storage device. The state of the energy storage device means a state of the energy storage device up to the current time, and may be, for example, a state related to a usage history or a type of the energy storage device. The usage history of the energy storage device includes information such as a temperature range in which the energy storage device has been used up to the current time and an SOC range in which the energy storage device has been used. The type of the energy storage device includes design information of the energy storage device. A correspondence relationship between a capacity and an internal state amount of the energy storage device depends on a state of the energy storage device. By specifying the correspondence relationship between the capacity of the energy storage device and the internal state amount in consideration of the state transition of the energy storage device, the estimation accuracy of overall discharge characteristics can be improved.

(5) In the estimation device according to any one of (2) to (4) above, the adjustment portion may generate the correspondence relationship, based on the partial charge/discharge profile.

According to the estimation device according to the above (5), since the correspondence relationship is acquired during operation of the energy storage device, it is not necessary to set the correspondence relationship in advance, and the overall discharge characteristics can be estimated more easily.

(6) In the estimation device according to any one of the above (1) to (5), the estimation portion may estimate the overall discharge characteristic of the energy storage device, based on the parameter, and a positive electrode monopolar characteristic and a negative electrode monopolar characteristic of the energy storage device.

The “positive electrode monopolar characteristic” means a characteristic indicated by a positive electrode discharge curve. The “negative electrode monopolar characteristic” means a characteristic indicated by a negative electrode discharge curve. According to the estimation device according to the above (6), the overall discharge characteristic can be efficiently estimated from a difference between the positive electrode monopolar characteristic and the negative electrode monopolar characteristic of the energy storage device corresponding to the adjusted internal state amount parameter.

(7) In the estimation device according to any one of (1) to (6) above, the parameter may include a positive electrode effectiveness and a charge reserve capacity of a negative electrode.

According to the estimation device according to the above (7), by adjusting an index indicating the internal state of the energy storage device, the shape of the overall discharge characteristic can be suitably adjusted.

(8) A diagnostic device according to an aspect of the present disclosure includes a processing unit that diagnoses a capacity of an energy storage device, based on the overall discharge characteristic estimated by the estimation device according to any one of (1) to (7) above.

According to the above configuration, the full charge capacity of the energy storage device can be diagnosed from an actual operation pattern without stopping the operation of the energy storage system or without operating the energy storage system in a specific operation pattern.

(9) An estimation method according to an aspect of the present disclosure includes: acquiring time-series data of a current and a voltage of an energy storage device; calculating time-series data of an amount of electricity or an SOC, based on the acquired time-series data of the current;

generating a partial charge/discharge profile of the energy storage device, based on the acquired time-series data of the current and the calculated time-series data of the amount of electricity or the SOC; and estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

(10) An estimation program according to an aspect of the present disclosure causes a computer to execute processes of: acquiring time-series data of a current and a voltage of an energy storage device; calculating time-series data of an amount of electricity or an SOC, based on the acquired time-series data of the current; generating a partial charge/discharge profile of the energy storage device, based on the acquired time-series data of the current and the calculated time-series data of the amount of electricity or the SOC; and estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

(11) A diagnostic method according to an aspect of the present disclosure uses a computer to execute processes of: acquiring time-series data of a current and a voltage of an energy storage device; calculating time-series data of an amount of electricity or an SOC, based on the acquired time-series data of the current; generating a partial charge/discharge profile of the energy storage device, based on the acquired time-series data of the current and the calculated time-series data of the amount of electricity or the SOC; estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile; and diagnosing a capacity of the energy storage device, based on the estimated overall discharge characteristic.

Hereinafter, the present disclosure will be specifically explained with reference to the drawings illustrating embodiments thereof.

### First Embodiment

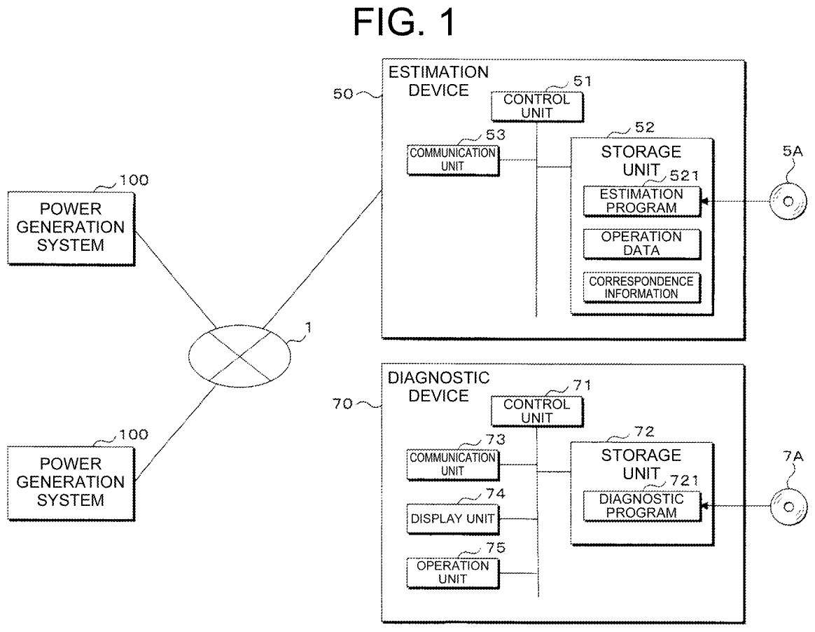

FIG. 1 is a diagram illustrating a configuration example of an estimation device 50 and a diagnostic device 70. The estimation device 50 and the diagnostic device 70 are communicatively connected to a communication network 1 such as the Internet. The estimation device 50 and the diagnostic device 70 may be integrated into either one of the estimation device 50 and the diagnostic device 70. A power generation system 100 is connected to the communication network 1. The number of power generation systems 100 may be one or three or more. The estimation device 50 and the diagnostic device 70 or one of the devices may be integrated into any one of the power generation systems 100.

The estimation device 50 and the diagnostic device 70 are, for example, a server computer, a personal computer, a quantum computer, or the like, and perform various kinds of information processing and transmission and reception of information. The estimation device 50 and the diagnostic device 70 will be described in detail below.

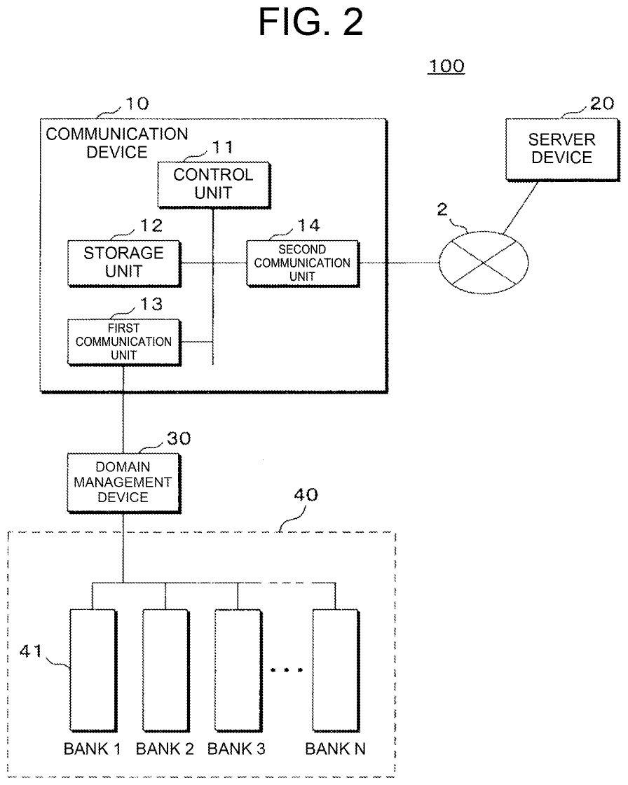

FIG. 2 is a diagram illustrating a configuration of the power generation system 100. The power generation system 100 includes a communication device 10, a server device 20 connected to the communication device 10 via a network 2, a domain management device 30, and an energy storage unit (domain) 40. The energy storage unit 40 may include a plurality of banks 41. The energy storage unit 40 is accommodated in, for example, a battery panel, and is used in a thermal power generation system, a mega solar power generation system, a wind power generation system, an uninterruptible power supply (UPS), a stabilized power supply system for railway, or the like. A portion of the energy storage unit 40 excluding a power conditioner (not illustrated) may be referred to as an energy storage system. The energy storage unit 40 is not limited to industrial applications, and may be for home use.

The estimation device 50, the diagnostic device 70, and the plurality of power generation systems 100 constitute a remote monitoring system. The remote monitoring system enables remote access to information regarding energy storage devices included in the power generation system 100. A business operator performs a business of designing, introducing, operating, and maintaining an energy storage system including the communication device 10, the domain management device 30, and the energy storage unit 40, and the energy storage system can be remotely monitored by the remote monitoring system.

The communication device 10 includes a control unit 11, a storage unit 12, a first communication unit 13, and a second communication unit 14. The control unit 11 is constituted by a central processing unit (CPU) or the like, and controls the entire communication device 10 by using built-in memories such as a read only memory (ROM) and a random access memory (RAM).

The storage unit 12 includes, for example, a non-volatile storage device such as a flash memory. The storage unit 12 can store required information, and can store, for example, information acquired by processing of the control unit 11.

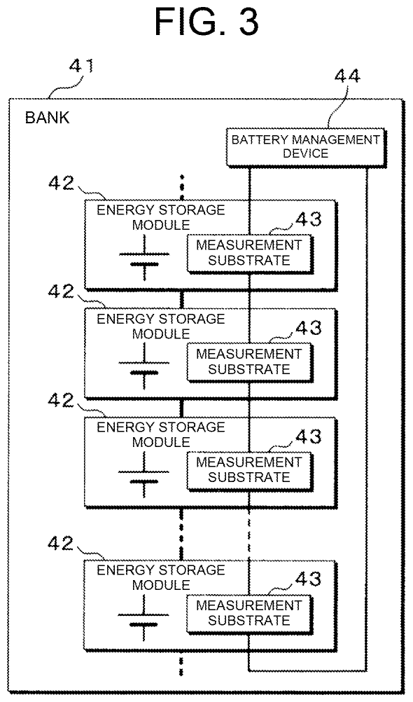

The first communication unit 13 includes a communication interface that achieves communication with the domain management device 30 (or the battery management device 44 illustrated in FIG. 3). The control unit 11 can communicate with the domain management device 30 through the first communication unit 13.

The second communication unit 14 includes a communication interface that achieves communication via the network 2. The control unit 11 can communicate with the server device 20 through the second communication unit 14.

The domain management device 30 transmits and receives information to and from each bank 41 by using a predetermined communication interface. The storage unit 12 can store operation data acquired via the domain management device 30.

The server device 20 can collect operation data of the energy storage system from the communication device 10. The operation data includes time-series data such as a current value, a voltage value, and temperature data of each energy storage device in the energy storage system.

The server device 20 stores the collected operation data by classifying the operation data for each energy storage device. The server device 20 can transmit the operation data to the estimation device 50 via the networks 2 and 1. Note that the networks 2 and 1 may be one communication network.

FIG. 3 is a diagram illustrating a configuration example of the bank 41. The bank 41 is formed by connecting a plurality of energy storage modules in series, and includes a battery management device (BMU: Battery Management Unit) 44, a plurality of energy storage modules 42, a measurement substrate (CMU: Cell Management Unit) 43 provided in each energy storage module 42, and the like.

In the energy storage module 42, a plurality of energy storage cells are connected in series. In the present specification, the “energy storage device” may mean an energy storage cell, an energy storage module 42, a bank 41, and a domain in which the banks 41 are connected in parallel. In the present embodiment, the measurement substrate 43 acquires information regarding a state of each energy storage cell of the energy storage module 42. The energy storage device information includes, for example, a voltage, a current, a temperature, a state of charge (SOC), a state of health (SOH), and the like of the energy storage cell. The energy storage device information can be repeatedly acquired at an appropriate cycle such as 0.1 seconds, 0.5 seconds, or 1 second, for example. Data in which the energy storage device information is accumulated serves as a part of the operation data. The “energy storage device” is preferably a secondary battery such as a lead-acid battery or a lithium-ion battery, or a rechargeable device such as a capacitor. A part of the energy storage devices may be a non-rechargeable primary battery.

The battery management device 44 communicates with the measurement substrate 43 with a communication function by serial communication, and can acquire energy storage device information detected by the measurement substrate 43. The battery management device 44 can transmit and receive information to and from the domain management device 30. The domain management device 30 aggregates energy storage device information from the battery management device 44 of the bank belonging to the domain. The domain management device 30 outputs the aggregated energy storage device information to the communication device 10. As described above, the communication device 10 can acquire operation data of the energy storage unit 40 via the domain management device 30. The communication device 10 transmits the acquired operation data to the estimation device 50 via the server device 20.

As illustrated in FIG. 1, the estimation device 50 includes a control unit 51, a storage unit 52, a communication unit 53, and the like. The estimation device 50 may be a multi-computer including a plurality of computers, or may be a virtual machine virtually constructed by software.

The control unit 51 is an arithmetic circuit including a CPU, a graphics processing unit (GPU), a ROM, a RAM, and the like. The CPU or GPU included in the control unit 51 executes various computer programs stored in the ROM or the storage unit 52, and controls the operation of each of the above-described hardware units. The control unit 51 may have functions of a timer that measures an elapsed time from when a measurement start instruction is given to when a measurement end instruction is given, a counter that counts the number of times, a clock that outputs date and time information, and the like.

The storage unit 52 includes a non-volatile storage device such as a flash memory or a hard disk drive. The storage unit 52 stores various computer programs to be executed by the control unit 51, data necessary for executing a computer program, and the like. The computer program stored in the storage unit 52 includes an estimation program 521 for causing a computer to execute processing related to estimation of an overall discharge characteristic.

The data stored in the storage unit 52 includes the operation data received from the power generation system 100 and information regarding a correspondence relationship between the discharge capacity of the energy storage device and the internal state amount parameter. As described above, the operation data includes time-series data of current values and voltage values of the energy storage devices in the power generation system 100. Correspondence information includes, for example, a correlation function, a correspondence table, a correspondence graph, or the like indicating a relationship between the discharge capacity and the internal state amount parameter. As the correspondence information, a plurality of types of information may be stored in accordance with the state of the energy storage device.

A computer program (program product) including the estimation program 521 may be provided by a non-transitory recording medium 5A in which the computer program is recorded in a readable format. The recording medium 5A is a portable memory such as a CD-ROM, a USB memory, or a secure digital (SD) card. The control unit 51 reads a desired computer program from the recording medium 5A by using a reading device (not illustrated), and stores the read computer program in the storage unit 52. Alternatively, the above-described computer program may be provided by communication. The estimation program 521 may be configured by a single computer program or a plurality of computer programs, and may be executed on a single computer or a plurality of computers interconnected by a communication network.

The communication unit 53 includes a communication interface that achieves communication via the network 1. The control unit 51 can communicate with an external device through the communication unit 53. Examples of the external device communicably connected to the communication unit 53 include the power generation system 100 and the diagnostic device 70. The control unit 51 receives operation data transmitted from the power generation system 100 through the communication unit 53. The control unit 51 transmits an estimation result of overall discharge characteristic to the diagnostic device 70 through the communication unit 53.

The estimation device 50 may include, for example, an operation unit for receiving an operation by a user, a display unit for displaying various kinds of information, and the like.

The diagnostic device 70 includes a control unit 71, a storage unit 72, a communication unit 73, a display unit 74, an operation unit 75, and the like. The diagnostic device 70 may be a multi-computer including a plurality of computers, or may be a virtual machine virtually constructed by software.

The control unit (processing unit) 71 is an arithmetic circuit including a CPU, a GPU, a ROM, a RAM, and the like. The CPU or GPU included in the control unit 71 executes various computer programs stored in the ROM or the storage unit 72, and controls the operation of each of the above-described hardware units. The control unit 71 may have functions of a timer that measures an elapsed time from when a measurement start instruction is given to when a measurement end instruction is given, a counter that counts the number of times, a clock that outputs date and time information, and the like.

The storage unit 72 includes a non-volatile storage device such as a flash memory or a hard disk drive. The storage unit 72 stores therein various computer programs to be executed by the control unit 71, data necessary to execute the computer programs, and the like. The computer program stored in the storage unit 72 includes a diagnostic program 721 for causing a computer to execute processing related to diagnosis of a discharge capacity.

The communication unit 73 includes a communication interface that achieves communication via the network 1. The control unit 71 can communicate with the estimation device 50 through the communication unit 73. The control unit 71 receives the estimation result of overall discharge characteristics transmitted from the estimation device 50, through the communication unit 73.

The display unit 74 includes, for example, a display device such as a liquid crystal display or an organic electroluminescence (EL) display. The display unit 74 displays various kinds of information in accordance with an instruction from the control unit 71. The operation unit 75 is an interface that receives an operation by a user. The operation unit 75 includes, for example, a keyboard, a touch panel device with a built-in display, a speaker, a microphone, and the like. The operation unit 75 receives an operation input from a user, and transmits a control signal according to the operation content to the control unit 71.

The diagnostic device 70 may be configured to receive an operation through an externally connected computer, and output information to be notified to the external computer. In this case, the diagnostic device 70 does not have to include the display unit 74 and the operation unit 75.

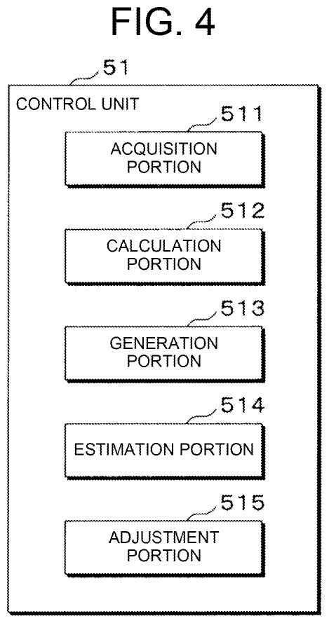

FIG. 4 is a functional block diagram illustrating a configuration example of the estimation device 50. The control unit 51 of the estimation device 50 reads and executes the estimation program 521 stored in the storage unit 52, thereby achieving functions of an acquisition portion 511, a calculation portion 512, a generation portion 513, an estimation portion 514, and an adjustment portion 515. Alternatively, some of these functions may be achieved by a dedicated hardware circuit (e.g., an FPGA or an ASIC) included in the control unit 51.

The acquisition portion 511 acquires time-series data of a current and a voltage of an energy storage device. The time-series data of the current and the voltage is data during charging or discharging of the energy storage device. The charging current or the discharging current does not have to be constant. Further, a region of an SOC or a region of the voltage during charging, and a region of the SOC or a region of the voltage during discharging may be limited. The acquisition portion 511 acquires time-series data in an actual operation pattern (not in an operation stop state or not in a specific operation pattern for capacity diagnosis) of an energy storage device. The time-series data may be real-time data or may be history data of a predetermined period in the past.

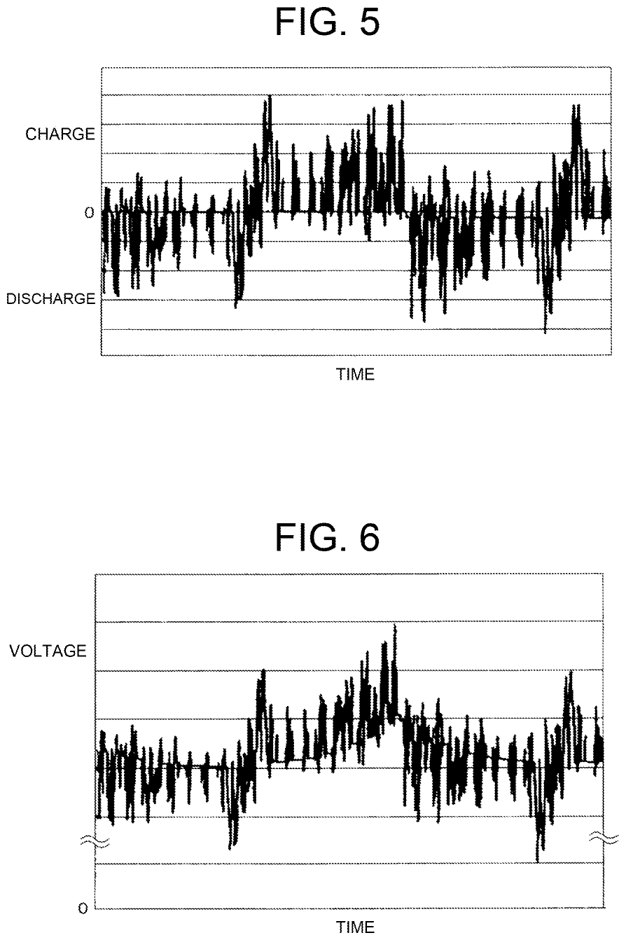

FIG. 5 is a diagram illustrating an example of current data, and FIG. 6 is a diagram illustrating an example of voltage data. In a graph illustrated in FIG. 5, the horizontal axis represents time, and the vertical axis represents current. In the vertical axis, a positive side represents charging, and a negative side represents discharging. As illustrated in FIG. 5, the acquisition portion 511 acquires time-series current data. In a graph illustrated in FIG. 6, the horizontal axis represents time, and the vertical axis represents voltage. The acquisition portion 511 acquires time-series voltage data, as illustrated in FIG. 6. The time-series data acquired by the acquisition portion 511 is stored in the storage unit 52.

The calculation portion 512 calculates time-series data of an amount of electricity, based on the time-series data of the current acquired by the acquisition portion 511. The amount of electricity can be obtained by current integration, and can be calculated by, for example, the following equation (1).

$$Q ( t ) = \sum I ( t ) \times Δ t \qquad ( 1 )$$

In the equation (1), Q is an amount of electricity, and I is a current value.

The generation portion 513 generates a partial charge/discharge profile of the energy storage device, based on the time-series data of the voltage acquired by the acquisition portion 511 and the time-series data of the amount of electricity calculated by the calculation portion 512.

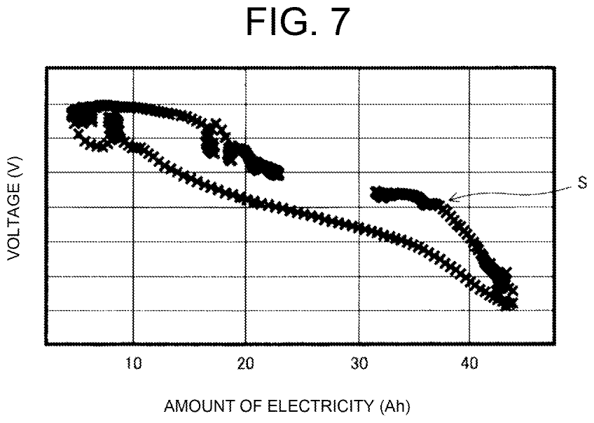

FIG. 7 is a diagram illustrating an example of a partial charge/discharge profile. FIG. 7 illustrates an example of a partial charge/discharge profile S in a state in which plots acquired for each predetermined period are overlapped. In a graph illustrated in FIG. 7, the horizontal axis represents an amount of electricity (Ah), and the vertical axis represents a voltage (V). On a two-dimensional coordinate in which the horizontal axis represents an amount of electricity and the vertical axis represents a voltage, the generation portion 513 can draw the partial charge/discharge profile S by, for example, plotting the amount of electricity calculated by the calculation portion 512 and a voltage at a time when the amount of electricity is acquired (a voltage corresponding to the amount of electricity).

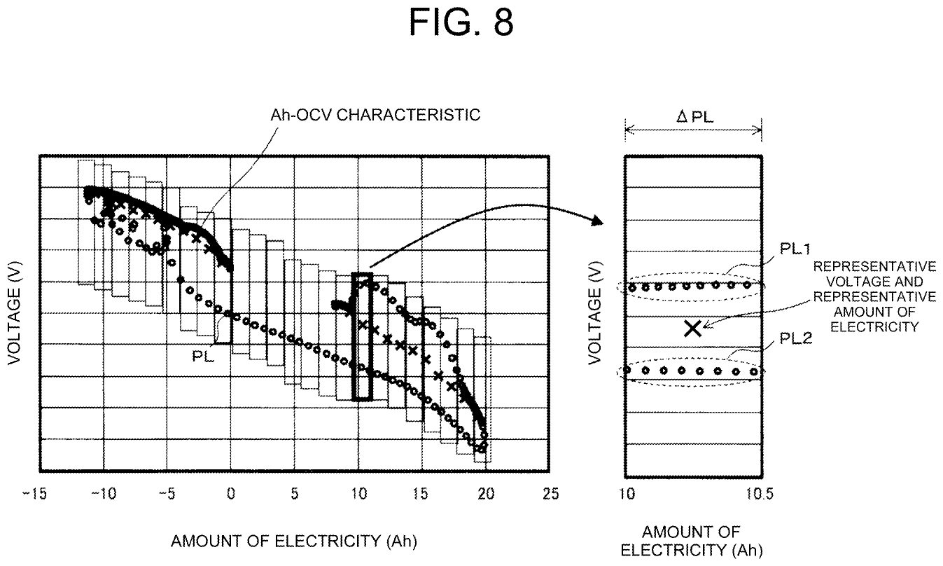

The generation portion 513 may generate a partial charge/discharge profile by performing predetermined processing on the above-described electricity amount/voltage plot. FIG. 8 is a diagram illustrating another example of the partial charge/discharge profile. In a graph illustrated in FIG. 8, the horizontal axis represents an amount of electricity (Ah), and the vertical axis represents a voltage (V).

The generation portion 513 generates an electricity amount/voltage plot (Ah-V plot) PL of the energy storage device over a required period, based on the time-series data of the voltage acquired by the acquisition portion 511 and the time-series data of the amount of electricity calculated by the calculation portion 512. Each white circle in FIG. 8 indicates (Ah-V plot) PL. The (Ah-V plot) PL can be drawn by, for example, plotting time-series data of an amount of electricity and a voltage on the two-dimensional coordinate in which the horizontal axis represents the amount of electricity and the vertical axis represents the voltage.

As the required period, an appropriate period such as one day, one week, one month, three months, or six months can be used, and for example, the required period may be set with reference to a period in which the operation pattern (usage history) of the energy storage devices does not differ greatly, a period in which an electricity amount calculation error when calculating an amount of electricity by integrating current does not exceed an allowable range, or the like.

The generation portion 513 divides the generated (Ah-V plot) PL into divided regions acquired by dividing the amount of electricity with a predetermined electricity amount width (ΔPL in FIG. 8). A diagram illustrated on the right side of FIG. 8 is an enlarged view of a divided region indicated by a rectangular frame in the graph.

The divided region is a vertically-long rectangular region having a predetermined electricity amount width ΔPL in the horizontal direction and a voltage (V) in the vertical direction. In each divided region, a part of the (Ah-V plot) PL is plotted. In FIG. 8, (Ah-V plots) PL1 and PL2 are plotted in the divided region ΔPL.

The generation portion 513 calculates, from the (Ah-V plot) in each divided region, a representative amount of electricity and a representative voltage representing the amount of electricity and the voltage for each divided region. Regarding the representative amount of electricity and the representative voltage, for example, an average value of voltages represented by the (Ah-V plot) in the divided region may be set as the representative voltage, and a center of an electricity amount width of the divided region may be set as the representative amount of electricity.

The generation portion 513 generates a partial charge/discharge profile of a required period, based on the representative amount of electricity and the representative voltage for each divided region. As indicated by a cross mark in FIG. 8, a partial charge/discharge profile (Ah-OCV characteristic) can be drawn by plotting the representative amount of electricity and the representative voltage for each divided region on the two-dimensional coordinate in which the horizontal axis represents the amount of electricity and the vertical axis represents the voltage. Accordingly, it is possible to generate a partial charge/discharge profile in a required period (e.g., a period in which an operation pattern of an energy storage device does not greatly differ, a period in which a calculation error of an amount of electricity does not exceed an allowable range, etc.). In the above description, the Ah-OCV characteristic based on the time-series data of the amount of electricity and the voltage has been exemplified as the partial charge/discharge profile. Alternatively, the partial charge/discharge profile may be an SOC-OCV characteristic based on time-series data of the SOC and the voltage.

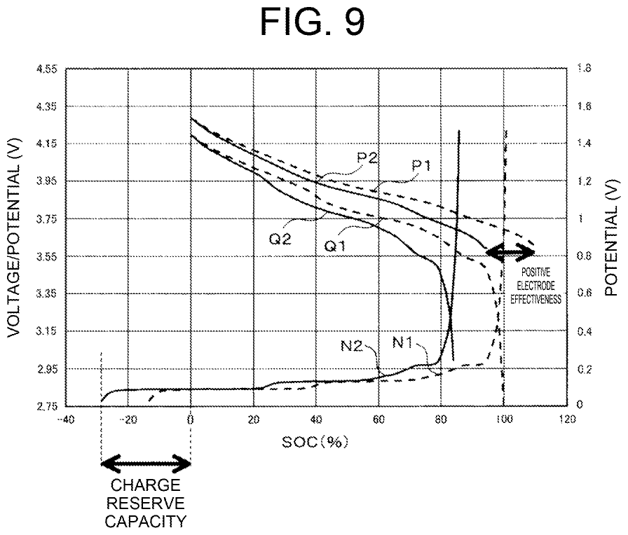

The estimation portion 514 estimates an overall discharge characteristic of an energy storage device, based on a positive electrode monopolar characteristic and a negative electrode monopolar characteristic of the energy storage device. The positive electrode monopolar characteristic is a characteristic indicated by a discharge curve of a positive electrode (e.g., counter electrode lithium) The discharge curve of the positive electrode may be acquired by plotting a discharge capacity and a potential corresponding to the capacity, with the horizontal axis representing the discharge capacity and the vertical axis representing the potential (see FIG. 9). The negative electrode monopolar characteristic is a characteristic indicated by a discharge curve of a negative electrode (e.g., lithium). The discharge curve of the negative electrode may be acquired by plotting a discharge capacity and a potential corresponding to the discharge, with the horizontal axis representing the discharge capacity and the vertical axis representing the potential (see FIG. 9).

A difference between the potential of the positive electrode and the potential of the negative electrode is a voltage of the energy storage device. The estimation portion 514 can estimate an overall discharge curve by calculating a difference between the potential of the positive electrode discharge curve and the potential of the negative electrode discharge curve, which correspond to each amount of electricity (capacity). The overall discharge characteristic may be a characteristic indicated by an overall discharge curve.

The estimation portion 514 receives an internal state amount parameter from the adjustment portion 515 in the estimation of the overall discharge characteristic. The estimation portion 514 estimates an overall discharge characteristic by using the positive electrode monopolar characteristic and the negative electrode monopolar characteristic, which correspond to the received internal state amount parameter.

The adjustment portion 515 adjusts the internal state amount parameter in such a way that the overall discharge characteristic estimated by the estimation portion 514 approaches the partial charge/discharge profile generated by the generation portion 513. The internal state amount parameter adjusted by the adjustment portion 515 is output to the estimation portion 514 again, and the estimation of the overall discharge characteristics is repeatedly performed. A plausible overall discharge characteristic is estimated by the optimized internal state amount parameter. The adjustment portion 515 may be a part of the estimation portion 514.

Hereinafter, a method of adjusting the internal state amount parameter and estimating the overall discharge characteristic will be explained in detail.

FIG. 9 is a diagram explaining an internal state amount parameter. In a graph illustrated in FIG. 9, the horizontal axis represents an SOC (%), the left vertical axis represents a voltage (V), and the right vertical axis represents a current (A). FIG. 9 illustrates a positive electrode discharge curve P, a negative electrode discharge curve N, and an overall discharge curve Q.

In FIG. 9, two positive electrode discharge curves P1 and P2 are illustrated. For example, the positive electrode discharge curve P1 corresponds to a positive electrode effectiveness of 1, and the positive electrode discharge curve P2 corresponds to a positive electrode effectiveness of a value smaller than 1. The positive electrode effectiveness (utilization rate) is an example of the internal state amount parameter, and is an index indicating a usable amount of an active material in the positive electrode. When the positive electrode effectiveness is 1, the energy storage device is the same as a new product, and the positive electrode effectiveness decreases as deterioration progresses. As the positive electrode effectiveness decreases, the positive electrode discharge curve changes in such a way as to be scaled in the horizontal axis direction.

In FIG. 9, two negative electrode discharge curves N1 and N2 are illustrated. For example, the negative electrode discharge curve N1 has a charge reserve capacity (deviation from 0. Ah to the negative side) of about 10 Ah (about 15% in SOC), and the negative electrode discharge curve N2 corresponds to a value where the charge reserve capacity is larger than 10 Ah. The charge reserve capacity is an example of the internal state amount parameter, and is an index indicating growth of a solid electrolyte interphase (SEI) film. As the charge reserve capacity increases, the negative electrode discharge curve changes in such a way as to move in parallel to the left side (negative side) in the horizontal axis direction. The charge reserve capacity may be represented by a discharge start position of the negative electrode (a relative position of the negative electrode).

An overall discharge curve Q1 illustrated in FIG. 9 indicates an overall discharge characteristic (SOC-V characteristic) acquired from the positive electrode discharge curve P1 and the negative electrode discharge curve N1, and an overall discharge curve Q2 indicates an overall discharge characteristic (SOC-V characteristic) acquired from the positive electrode discharge curve P2 and the negative electrode discharge curve N2. As illustrated in FIG. 9, the overall discharge curve Q also changes in response to a change in the positive electrode discharge curve P and the negative electrode discharge curve N. The discharge capacity can be calculated by subtracting an amount of electricity (capacity) corresponding to the upper limit voltage from an amount of electricity (capacity) corresponding to the lower limit voltage of the overall discharge characteristic. Note that, in FIG. 9, the horizontal axis is represented by SOC, but the horizontal axis may also be capacity.

The internal state amount parameter may include a discharge reserve capacity or a discharge start position of the positive electrode (relative position of the positive electrode), instead of or in addition to the above-described internal state amount parameter. The discharge reserve capacity and the discharge start position of the positive electrode are indices indicating oxidative decomposition of the electrolyte.

As described above, the overall discharge characteristic depends on the internal state amount parameter. The estimation device 50 adjusts the internal state amount parameter in such a way that the overall discharge characteristic approaches the partial charge/discharge profile. The estimation device 50 adjusts the internal state amount parameter by using information stored in the storage unit 52, which indicates a correspondence relationship between the discharge capacity of the energy storage device and the internal state amount parameter.

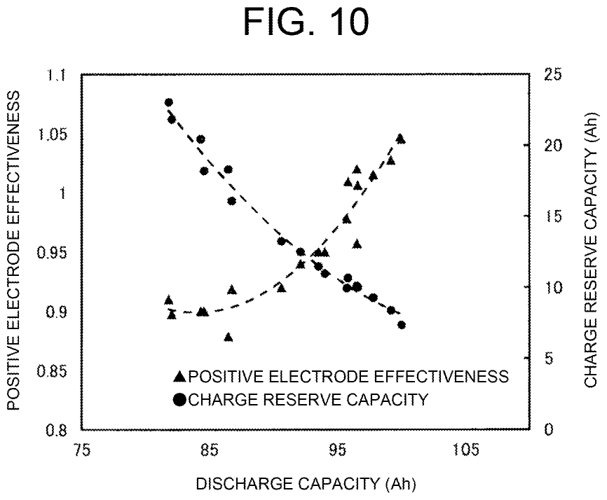

FIG. 10 is a diagram illustrating an example of a correspondence relationship between a discharge capacity of an energy storage device and an internal state amount parameter. In a graph illustrated in FIG. 10, the horizontal axis represents a discharge capacity (Ah), the left vertical axis represents a positive electrode effectiveness (no unit), and the right vertical axis represents a charge reserve capacity (Ah). In the graph of FIG. 10, a black triangle mark indicates a positive electrode activity, and a black circle mark indicates a charge reserve capacity. The internal state amount parameter depends on the discharge capacity. For example, as illustrated in FIG. 10, a value of the positive electrode effectiveness increases as a capacity value increases. As the capacity value increases, a value of the charge reserve capacity decreases. By using such a correspondence relationship, a value of each internal state amount parameter corresponding to a certain capacity value can be specified. The graph of the correspondence relationship illustrated in FIG. 10 is merely an example, and is not limited to this example. The value of the internal state amount parameter corresponding to the discharge capacity is not limited to one, and may be two or more. The correspondence relationship may be any as long as it includes information capable of limiting the value of the internal state amount parameter associated with the discharge capacity.

The estimation device 50 acquires, as learning data, continuous discharge characteristics with respect to capacity deterioration, based on actually measured data of a battery test, for example, and analyzes the acquired discharge characteristics, thereby obtaining a correspondence relationship between a discharge capacity (amount of electricity) and an internal state amount parameter. The estimation device 50 stores the obtained correspondence relationship in the storage unit 52 in a data format such as a function expression or a correspondence table.

The above correspondence relationship may be set in consideration of a state of the energy storage device. For example, a plurality of correspondence tables may be prepared in accordance with a usage history and a type of the energy storage device. The estimation device 50 specifies a state of the usage history and type of the energy storage device, based on initial information and operation data of the energy storage device, and specifies an internal state amount parameter by using a correspondence table corresponding to the specified state of the energy storage device.

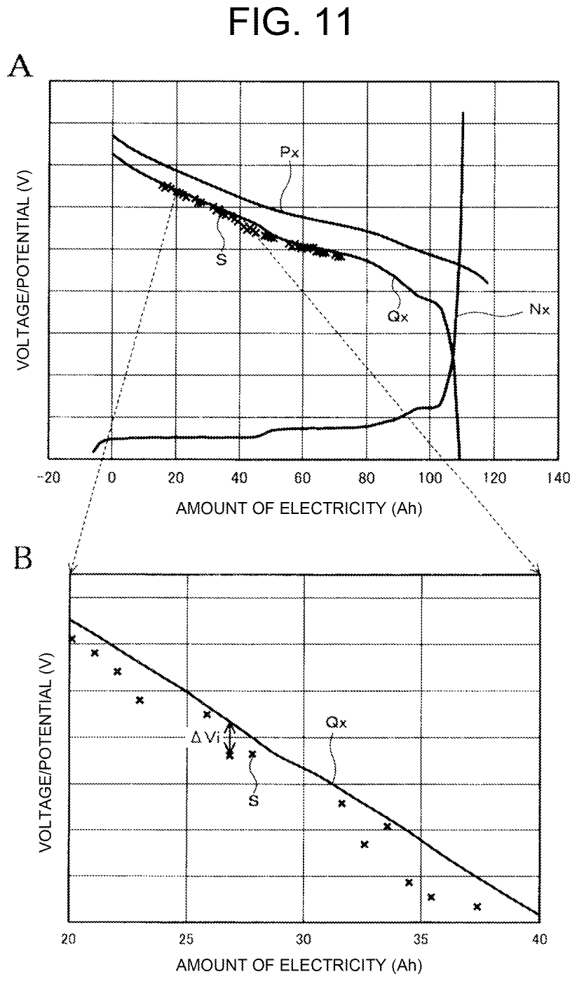

FIG. 11 is a diagram illustrating a method of estimating an overall discharge characteristic. In a graph illustrated in FIG. 11, the horizontal axis represents an amount of electricity (Ah), and the vertical axis represents a voltage or a potential (V). In FIG. 11A, an overall discharge curve Qx, a partial charge/discharge profile S, a positive electrode discharge curve Px, and a negative electrode discharge curve Nx are illustrated.

The estimation device 50 sets an arbitrary capacity value, and specifies, for each internal state amount parameter, a value of the internal state amount parameter associated with the set capacity value, based on a correspondence relationship between the discharge capacity and the internal state amount parameter. Based on the specified value of each internal state amount parameter, the estimation device 50 generates a positive electrode discharge curve Px and a negative electrode discharge curve Nx corresponding to the value of each internal state amount parameter. The estimation device 50 generates an overall discharge curve Qx from the generated positive electrode discharge curve Px and negative electrode discharge curve Nx.

The estimation device 50 adjusts the capacity value in such a way that a voltage corresponding to a certain amount of electricity of the overall discharge curve Qx approaches a voltage corresponding to the amount of electricity of the partial charge/discharge profile S, in a section of the overall discharge curve Qx corresponding to the partial charge/discharge profile S. The section corresponding to the partial charge/discharge profile S may be a section including an amount of electricity corresponding to the partial charge/discharge profile S, among the amounts of electricity in the overall discharge curve Qx.

As illustrated in an enlarged manner in FIG. 11B, the estimation device 50 adjusts the capacity value in such a way as to minimize a sum of squares (ΣΔVi²) of a voltage difference ΔVi between a voltage of the partial charge/discharge profile S corresponding to a certain amount of electricity in the above-described section and a voltage of the overall discharge curve Qx. The estimation device 50 may handle voltages corresponding to all the amounts of electricity on the partial charge/discharge profile S. Namely, a linear sum d of the above-described sum of squares (ΣΔVi²) in the section may be minimized.

The estimation device 50 acquires, as an optimal overall discharge characteristic, an overall discharge characteristic generated by using an internal state amount parameter corresponding to a capacity value in which the sum of squares (ΣΔVi²) or a linear sum d thereof is minimized. The above-described capacity value corresponds to a discharge capacity obtained by the optimal overall discharge characteristic.

As described above, by utilizing the correspondence relationship between the discharge capacity and the internal state amount parameter, it is possible to efficiently extract a value of the internal state amount parameter in the adjustment process for approximating the overall discharge characteristic to the partial charge/discharge profile.

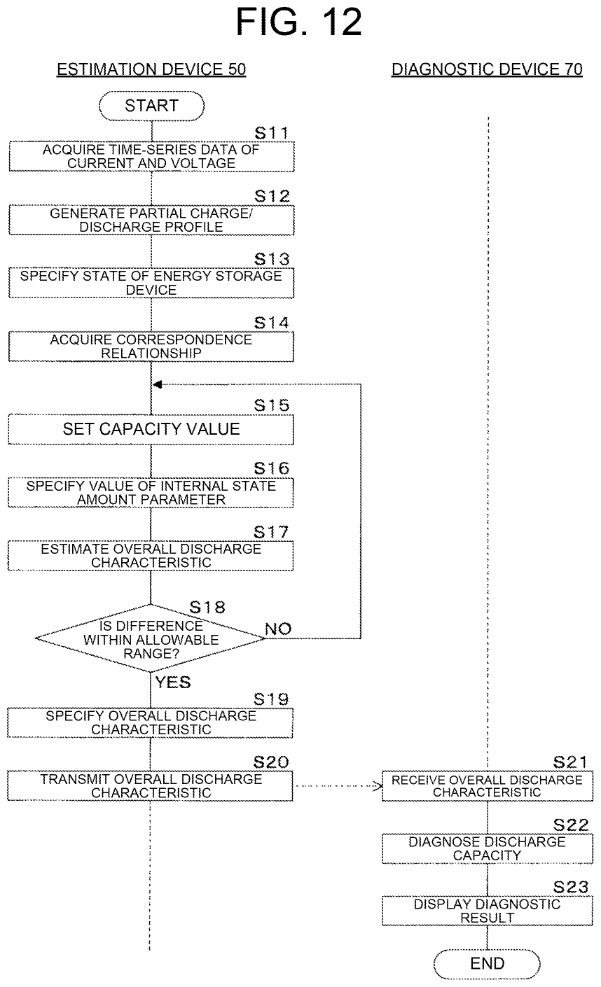

FIG. 12 is a flowchart illustrating an example of a processing procedure to be executed by the estimation device 50 and the diagnostic device 70. The processing in the following flowchart is executed by the control unit 51 according to the estimation program 521 stored in the storage unit 52 of the estimation device 50, and is executed by the control unit 71 according to the diagnostic program 721 stored in the storage unit 72 of the diagnostic device 70.

The control unit 51 of the estimation device 50 acquires time-series data of a current and a voltage of the energy storage device (step S11). The control unit 51 generates a partial charge/discharge profile (step S12).

The control unit 51 specifies the state of the usage history and type of the energy storage device, for example, based on the initial information of the energy storage device stored in advance and the acquired operation data (step S13). The control unit 51 acquires a correspondence relationship corresponding to the specified state of the energy storage device, from among the plurality of correspondence relationships stored in the storage unit 52 (step S14). When there is one correspondence relationship stored in the storage unit 52, step S13 may be omitted.

The control unit 51 sets a capacity value (step S15), and specifies a value of the internal state amount parameter corresponding to the set capacity value, based on the correspondence relationship between the discharge capacity and the internal state amount parameter, which is acquired in step S14 (step S16).

The control unit 51 estimates the overall discharge characteristic, based on the positive electrode monopolar characteristic and the negative electrode monopolar characteristic corresponding to the specified value of the internal state amount parameter (step S17).

The control unit 51 determines whether or not a difference between a voltage in a section corresponding to the partial charge/discharge profile of the estimated overall discharge characteristic and a voltage of the partial charge/discharge profile is within an allowable range (step S18).

When it is determined that the difference is not within the allowable range (step S18: NO), the control unit 51 returns the processing to step S15. The control unit 51 adjusts the discharge capacity value according to a predetermined rule, and repeats the processing in step S15 and subsequent steps. As an example, the control unit 51 may adjust the discharge capacity value by adding or subtracting a predetermined value to or from the initial capacity value.

When it is determined that the difference is within the allowable range (step S18: YES), the control unit 51 specifies the acquired overall discharge characteristic as the overall discharge characteristic of the energy storage device (step S19). The control unit 51 transmits an estimation result regarding the specified overall discharge characteristic to the diagnostic device 70 (step S20).

The control unit 71 of the diagnostic device 70 receives the estimation result regarding the overall discharge characteristic (step S21). The control unit 71 diagnoses the discharge capacity of the energy storage device, based on the received overall discharge characteristic (step S22). The discharge capacity is obtained by subtracting an amount of electricity corresponding to the upper limit voltage from an amount of electricity corresponding to the lower limit voltage of the overall discharge characteristic. The value of the discharge capacity diagnosed from the overall discharge characteristic corresponds to the capacity value (optimal capacity value) adjusted in the processing from step S15 to step S18. The control unit 71 displays a diagnostic result of the discharge capacity on the display unit 74 (step S23), and ends the series of processes.

In the above description, the capacity value is adjusted by sequential calculation. Alternatively, the estimation device 50 may set a plurality of capacity values by changing the capacity value at predetermined value intervals, and select an overall discharge characteristic that minimizes the difference in voltage, from among a plurality of overall discharge characteristics generated based on the internal state amount parameter corresponding to each set capacity value. A capacity value corresponding to the selected overall discharge characteristic is specified as an optimal capacity value.

According to the present embodiment, it is possible to estimate the overall discharge characteristic and diagnose the discharge capacity without stopping the operation of the energy storage device or operating the energy storage device in a specific operation pattern for capacity diagnosis. Further, the overall discharge characteristics can be estimated with accuracy, regardless of the type of a load of the energy storage device. By using the correspondence relationship between the discharge capacity and the internal state amount parameter, a combination value of a plurality of internal state amount parameters for generating the overall discharge characteristics can be efficiently specified.

### Second Embodiment

In a second embodiment, a correspondence relationship between a discharge capacity and an internal state amount parameter is generated during operation of an energy storage device.

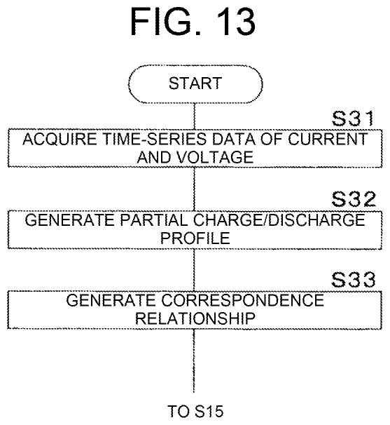

FIG. 13 is a flowchart illustrating an example of a processing procedure to be executed by the estimation device 50 according to the second embodiment.

The control unit 51 of the estimation device 50 executes the same processing as that from step S11 to step S12 in FIG. 12, acquires time-series data of a current and a voltage (step S31), and generates a partial charge/discharge profile (step S32).

The control unit 51 generates a correspondence relationship between the discharge capacity and the internal state amount parameter by analyzing the acquired partial charge/discharge profile (step S33). The control unit 51, for example, analyzes a partial charge/discharge profile in which an electricity amount region is limited, thereby plotting, for a limited discharge capacity (amount of electricity), the discharge capacity and an internal state amount parameter corresponding to the discharge capacity, with the horizontal axis representing the discharge capacity and the vertical axis representing the internal state amount parameter. The control unit 51 obtains an approximate expression of the acquired plot, thereby obtaining a correlation function indicating a correspondence relationship between a discharge capacity and the internal state amount parameter related to a total discharge capacity.

Thereafter, the control unit 51 executes the processing of step S15 and the subsequent steps illustrated in FIG. 12, thereby performing a process of estimating the overall discharge characteristic, based on the generated correspondence relationship.

According to the present embodiment, it is not necessary to prepare a correspondence relationship between the discharge capacity and the internal state amount parameter in advance, and the overall discharge characteristic can be more easily estimated. By generating the correspondence relationship from the operation data of the energy storage device, it is possible to generate a correspondence relationship suitably reflecting a state of the energy storage device to be estimated.

The embodiment disclosed herein is illustrative in all respects and it is ought to be understood not restrictive. The technical features described in the respective embodiments can be combined with each other, and the scope of the present invention is intended to include all modifications within the scope of the claims and a scope equivalent to the scope of the claims. The sequence illustrated in each embodiment is not limited, and each processing procedure may be executed by changing the order thereof as long as there is no internal contradiction, or a plurality of processes may be executed in parallel. A processing subject of each process is not limited, and the processing of each device may be executed by another device as long as there is no internal contradiction.

The matters described in the respective embodiments can be combined with each other. Furthermore, the independent claims and the dependent claims recited in the claims can be combined with each other in any combination, regardless of the citation form. Furthermore, in the scope of claims, a form (multi-claim form) in which a claim citing two or more other claims is recited is used, but the present invention is not limited thereto. The present invention may be described by using a format of describing a multi-claim (multi-multi-claim) in which at least one multi-claim is cited.

1. An estimation device, comprising:
an acquisition portion that acquires time-series data of a current and a voltage of an energy storage device;
a calculation portion that calculates time-series data of an amount of electricity or an SOC, based on the time-series data of the current acquired by the acquisition portion;
a generation portion that generates a partial charge/discharge profile of the energy storage device, based on the time-series data of the current acquired by acquisition portion and the time-series data of the amount of electricity or the SOC calculated by the calculation portion; and
an estimation portion that estimates an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

2. The estimation device according to claim 1, comprising: an adjustment portion that adjusts the parameter, based on a correspondence relationship between a capacity of the energy storage device and the parameter.

3. The estimation device according to claim 2, wherein the adjustment portion adjusts the parameter in such a way that a profile of a predetermined section in the overall discharge characteristic related to a capacity associated with the parameter approaches the partial charge/discharge profile.

4. The estimation device according to claim 2, wherein
a plurality of the correspondence relationships are set in accordance with a state of the energy storage device, and
the adjustment portion selects a correspondence relationship to be used for specifying the parameter in accordance with the state of the energy storage device.

5. The estimation device according to claim 2, wherein the adjustment portion generates the correspondence relationship, based on the partial charge/discharge profile.

6. The estimation device according to claim 1, wherein the estimation portion estimates the overall discharge characteristic of the energy storage device, based on the parameter, and a positive electrode monopolar characteristic and a negative electrode monopolar characteristic of the energy storage device.

7. The estimation device according to claim 1, wherein the parameter includes a positive electrode effectiveness and a charge reserve capacity of a negative electrode.

8. A diagnostic device comprising: a processing unit that diagnoses a capacity of an energy storage device, based on the overall discharge characteristic estimated by the estimation device according to claim 1.

9. An estimation method causing a computer to execute processes of:
acquiring time-series data of a current and a voltage of an energy storage device;
calculating time-series data of an amount of electricity or an SOC, based on the acquired time-series data of the current;
generating a partial charge/discharge profile of the energy storage device, based on the acquired time-series data of the current and the calculated time-series data of the amount of electricity or the SOC; and
estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

10. A non-transitory computer readable medium having recorded therein an estimation program for causing a computer to execute processes of:
acquiring time-series data of a current and a voltage of an energy storage device;
calculating time-series data of an amount of electricity or an SOC, based on the acquired time-series data of the current;
generating a partial charge/discharge profile of the energy storage device, based on the acquired time-series data of the current and the calculated time-series data of the amount of electricity or the SOC; and
estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile.

11. A diagnostic method causing a computer to execute processes of:
acquiring time-series data of a current and a voltage of an energy storage device;
calculating time-series data of an amount of electricity or an SOC, based on the acquired time-series data of the current;
generating a partial charge/discharge profile of the energy storage device, based on the acquired time-series data of the current and the calculated time-series data of the amount of electricity or the SOC;
estimating an overall discharge characteristic of the energy storage device, based on a parameter representing an internal state amount of the energy storage device, the parameter being adjusted in such a way that a profile of a predetermined section in the overall discharge characteristic of the energy storage device approaches the partial charge/discharge profile; and
diagnosing a capacity of the energy storage device, based on the estimated overall discharge characteristic.
